(19) United States
(12) Patent Application Publication
(10) Pub. No.: US 2022/0297311 A1
(43) Pub. Date: Sep. 22, 2022

(54) JOINING AND/OR INSPECTION UNIT

(71) Applicant: Liebherr-Verzahntechnik GmbH, Kempten (DE)

(72) Inventors: Florian Hoessle, Sonthofen (DE); Markus ZOLLITSCH, Haldenwang (DE); Jan POLLMANN, Kempten (DE)

(21) Appl. No.: 17/655,502

(22) Filed: Mar. 18, 2022

(30) Foreign Application Priority Data
Mar. 18, 2021 (DE) 10 2021 106 597.6

(51) Int. Cl. B25J 15/00; H01M 10/04; H01M 10/42; B25J 13/08

(52) U.S. Cl. CPC B25J 15/0028; H01M 10/0404; H01M 10/4285; B25J 13/082; B23P 19/06

(57) ABSTRACT

The present disclosure comprises a joining and/or inspection unit for joining and/or inspecting a component having a base and a plurality of joining and/or inspection elements, wherein the joining and/or inspection elements are arranged at the base such that they each establish a connection and/or carry out an inspection at a joining and/or inspection point of the component. The joining and/or inspection elements can be arranged at the base via an adjustment arrangement that allows an adjustment of the spacing of the joining and/or inspection elements from one another, with the adjustment arrangement preferably comprising a first and second adjustment axle via which the spacing of the joining and/or inspection elements from one another is adjustable in a first and second direction.

### CROSS-REFERENCE TO RELATED APPLICATION

The present application claims priority to German Patent Application No. 10 2021 106 597.6 filed on Mar. 18, 2021. The entire contents of the above-listed application is hereby incorporated by reference for all purposes.

### TECHNICAL FIELD

The present disclosure relates to a joining and/or inspection unit for joining and/or inspecting a component having a base and a plurality of joining and/or inspection elements, wherein the joining and/or inspection elements are arranged at the base such that they each establish a connection and/or carry out an inspection at a joining and/or inspection point of the component.

### BACKGROUND

Such joining and/or inspection units can be arranged, for example, at a robot arm to install and/or to inspect components. The joining and/or inspection elements can, for example, be screwdrivers or measuring devices for inspecting electrical properties of the component. The joining and/or inspection unit is in particular used for joining and/or inspecting battery elements such as battery modules or housing parts of battery packs or battery packs, in particular for electrically or hybrid electrically driven vehicles.

The present disclosure further relates to a joining and/or inspection unit that furthermore comprises a gripper in addition to one or more joining and/or inspection elements.

### SUMMARY

Known joining and/or inspection units are typically designed specifically for joining and/or inspecting a single component and are in particular adapted to the position of the joining and/or inspection points of the component with regard to the geometrical arrangement of the joining and/or inspection elements.

It is the object of the present disclosure to provide an improved joining and/or inspection unit.

This object is achieved by joining and/or inspection units.

In a first aspect, the present disclosure comprises a joining and/or inspection unit for joining and/or inspecting a component having a base and a plurality of joining and/or inspection elements, wherein the joining and/or inspection elements are arranged at the base such that they each establish a connection and/or carry out an inspection at a joining and/or inspection point of the component. Provision is made here that the joining and/or inspection elements are arranged at the base via an adjustment arrangement that permits an adjustment of the spacing of the joining and/or inspection elements from one another.

The present disclosure hereby allows a flexible adaptation of the joining and/or inspection unit to different components and in particular to components having a different geometrical arrangement of the joining and/or inspection points of the component. The joining and/or inspection of such different components is hereby possible using the same joining and/or inspection unit.

The adjustment of the spacing of the joining and/or inspection elements in accordance with the first aspect can in particular be implemented by one of the following variants:

In a first variant of the present disclosure, the joining and/or inspection unit can comprise a plurality of joining elements, with the adjustment arrangement allowing an adjustment of the spacing of the joining elements from one another.

In a second variant of the present disclosure, the joining and/or inspection unit can comprise a plurality of inspection elements, with the adjustment arrangement allowing an adjustment of the spacing of the inspection elements from one another.

In a third variant of the present disclosure, the joining and/or inspection unit can comprise at least one joining element and at least one inspection element, with the adjustment arrangement allowing an adjustment of the spacing of the joining element from the inspection element.

The three variants can also be combined with one another.

In a possible embodiment, the adjustment arrangement comprises a first and a second adjustment axle via which the spacing of the joining and/or inspection elements from one another is adjustable in a first and second direction.

The first adjustment axle can effect an adjustment in accordance with one of the three aforesaid variants or a combination of these three variants.

The second adjustment axle can effect an adjustment in accordance with one of the three aforesaid variants or a combination of these three variants.

The first and second adjustment axles can effect either an adjustment in accordance with the same variant and/or a combination of variables or can effect an adjustment in accordance with different variants and/or combinations of variants.

In a possible embodiment, an axial direction of the first adjustment axle is perpendicular on an axial direction of the second adjustment axle.

In a possible embodiment, the spacing of the joining and/or inspection elements and/or of the joining and/or inspection points is adjustable in a plane by the first and second adjustment axles. This plane can in particular be perpendicular on a joining and/or inspection direction. The joining and/or inspection direction can be a direction in which the joining and/or inspection element is moved at the joining and/or inspection point.

In a possible embodiment, the joining and/or inspection unit comprises at least one gripper to grip the component. The joining and/or inspection unit can in this case in particular be used for installing and/or handling the component by means of the gripper, with the component being joined and/or inspected by the joining and/or inspection element.

In a possible embodiment, the gripper allows a holding of the component in a desired position while the component is joined and/or inspected by the joining and/or inspection elements. The gripper can in particular hold the component in a desired position, in particular in a desired installation position.

A control is in particular provided by which the gripper grips the component and holds the component as part of an automatic installation and/or handling process while the component is joined and/or inspected by the joining and/or inspection elements.

In a possible embodiment, the control is configured such that the joining takes place while the gripper holds the component in a desired installation position.

In a possible embodiment, the control is configured such that the inspection takes place while the gripper moves the component in a desired installation position and/o holds It in a desired installation position.

In a possible embodiment, the gripper comprises at least two gripping actuators via which gripping elements for gripping the component can be actuated, with the gripping actuators being arranged at the base via the adjustment arrangement such that the spacing of the gripping actuators from one another is adjustable.

The present disclosure comprises in a second aspect a joining and/or inspection unit for joining and/or inspecting a component having a base, a gripper, and one or more joining and/or inspection elements, wherein the gripper comprises at least two gripping actuators via which gripping elements for gripping the component can be actuated, and wherein the joining and/or inspection element or elements are arranged at the base such that they each establish a connection and/or carry out an inspection at a joining and/or inspection point of the component. Provision is made in accordance with the second aspect that the gripping actuators and the joining and/or inspection element or elements is/are arranged at the base via an adjustment arrangement via which the spacing of the gripping actuators and/or of the joining and/or inspection element or elements from one another is adjustable.

The present disclosure hereby allows the flexible adaptation of the joining and/or inspection unit to different components and in particular to components having a different geometrical arrangement of the gripping, joining, and/or inspection points of the component. The gripping and the joining and/or inspection of such different components is hereby possible using the same joining and/or inspection unit.

The adjustment of the spacing of the gripping actuators and/or of the joining and/or inspection element or elements from one another in accordance with the second aspect can in particular be implemented by one of the following variants:

In a first variant of the present disclosure, the adjustment arrangement allows an adjustment of the spacing of the gripping actuators from one another.

In a second variant of the present disclosure, the adjustment arrangement allows an adjustment of the spacing of at least one gripping actuator from at least one joining and/or inspection element.

In a third variant of the present disclosure, the adjustment arrangement allows an adjustment of the spacing of the joining and/or inspection elements from one another. In this respect, the present disclosure in accordance with the second aspect comprises the variants described in accordance with the first variant and their combinations as subvariants.

The three variants of the second aspect can also be combined with one another.

Covered in a possible embodiment, the gripping actuator are adjustable with respect to one another in at least a first direction via at least a first adjustment axle.

Covered in a possible embodiment, the joining and/or inspection element or elements are adjustable with respect to the gripping actuators or to one another in at least a second direction via at least a second adjustment axle.

The present disclosure comprises joining and/or inspection units in accordance with the first and second aspects independently of one another.

The present disclosure, however, further also comprises joining and/or inspection units in which the features described with regard to the first and second aspects are implemented in combination.

Possible embodiments of a joining and/or inspection unit in accordance with the first and/or second aspects are shown in the following:

In a possible embodiment, the gripper is a mechanical gripper, with the gripping actuators moving the gripping elements along a first direction to grip the component.

The spacing between the gripping actuators can in this respect in particular be adjustable in the first direction by the adjustment arrangement to adapt the gripper to components of different sizes.

The gripper can, however, also be a pneumatic gripper and/or a magnetic gripper.

In a possible embodiment, the gripping actuators and the joining and/or inspection element or elements are adjustable together via at least a first adjustment axle.

In a possible embodiment, only the joining and/or inspection elements are adjustable via at least a second adjustment axle.

In a possible embodiment, a first gripping actuator is arranged together with a first joining and/or inspection element or with a group of first joining and/or inspection elements at an adjustable element of the first adjustment axle, in particular a slide.

In a possible embodiment, a second adjustment axle via which the first joining and/or inspection element or elements is/are adjustable with respect to one another and/or to the gripping actuator is arranged at the adjustable element.

In a possible embodiment, at least one adjustment axle is configured such that it carries out a symmetrical adjustment of at least two joining and/or inspection elements and/or gripping actuators relative to the base.

In a possible embodiment, the first and second adjustment axles are configured such that they each carry out a symmetrical adjustment of at least two joining and/or inspection elements and/or gripping actuators relative to the base.

In a possible embodiment, a first adjustment axle comprises two first slides that are travelable along a linear guide relative to the base via a first drive element, where the drive element may be a toothed rack and/or a belt drive.

In a possible embodiment, a second adjustment axle is arranged at each of the two first slides, with the second adjustment axle respectively comprising one or two second slides that is/are each travelable along a linear guide arranged at the first slide via a second drive element.

The second drive element can be a toothed rack and/or a belt drive.

In a possible embodiment, the two second adjustment axles that are arranged at the slides of the first adjustment axle are drivable together via a third drive element. The second drive elements are in particular drivable together via a third drive element.

in a possible embodiment, the joining and/or inspection unit comprises one or more fixing units for fixing the first and/or second adjustment axles, with there in particular being one or more clamping and/or latching units.

In a possible embodiment, the joining and/or inspection unit comprises one or more abutment elements that contact an upper side of the component to press it into position.

In a possible embodiment, the joining and/or inspection unit comprises a force measuring unit to measure a contact force.

In a possible embodiment, the force measuring unit is arranged between the base and an installation region for installing the joining and/or inspection unit at a handling arrangement, in particular a robot arm.

In a possible embodiment, the base comprises a frame whose main plane extends in parallel with the first direction of the first adjustment axle, in particular in parallel with a first direction in which the spacing of two gripping actuators is adjustable.

In a possible embodiment, the joining and/or inspection element or elements are arranged next to the frame at the second adjustment axle.

In a possible embodiment, the second adjustment axle and/or a slide of the first adjustment axle at which a second adjustment axle is arranged extend/extends through a cutout of the frame in a direction transverse to the main plane of the frame.

In a possible embodiment, the one or more joining and/or inspection elements are joining device and/or elements of a joining device and/or inspection devices. If they are elements of an inspection device, the inspection device can be arranged overall at the joining and/or inspection unit or the elements are in communication connection with other parts of the inspection device that are not arranged at the joining and/or inspection unit.

The one or more joining and/or inspection elements are in particular one or more of the following devices or elements:

screwdrivers or riveting devices, in particular having an automatic feed;

welding devices, in particular for spot welding;

actuation actuators for actuating a fastening element of the component;

elements of an inspection device for inspecting electrical properties of the component, in particular of a voltage, current, and/or resistance inspection device, in particular contact elements of a test device for inspecting electrical properties of the component.

In a possible embodiment, the joining and/or inspection unit comprises two or more joining elements, in particular two or more joining elements that carry out the same type of joining, in particular two or more identical joining elements.

In a possible embodiment, the joining and/or inspection unit comprises two or more inspection elements, in particular two or more contact elements of a test device for inspecting electrical properties of the component.

In a possible embodiment, the joining and/or comprises at least one inspection element and at least one joining element. The joining and/or can furthermore comprise at least two inspection elements and/or at least two jointing elements.

The joining and/or inspection unit can in particular be used for an automated installation, joining, and/or inspecting of the components. A control for the joining and/or inspection unit may be configured for this purpose to control the joining and/or inspection unit for an automated carrying out of these processes.

The control may be programmed to control the joining and/or inspection unit in an automated manner, as is described above or in the following with regard to the deployment and/or operating possibilities and/or the use and/or operation of the handling arrangement and/or of the joining and/or inspection unit.

The present disclosure furthermore comprises a handling station having a handling arrangement, in particular a robot, and a joining and/or inspection unit such as has been described above, with the joining and/or inspection unit being arranged at and being moved through the handling arrangement.

It can in particular be a handling station for the automated handling of the components, in particular for the automated installation, joining, and/or inspection of the components. The handling station may comprise a control for the handling arrangement and the joining and/or inspection unit that is configured to control the handling arrangement and the joining and/or inspection unit for the automated performance of these processes.

The control may be programmed to control the handling arrangement and the joining and/or inspection unit in an automated manner, as is described above or in the following with regard to the deployment and/or operating possibilities and/or the use and/or operation of the handling arrangement and/or of the joining and/or inspection unit.

The control of the handling station and/or for the joining and/or inspection unit may comprise a microprocessor and a non-volatile memory on which a program code is stored that runs on the microprocessor and here controls the handling arrangement and/or the joining and/or inspection unit in an automated manner. The microprocessor may be connected to sensors and/or actuators of the handling arrangement and of the joining and/or inspection unit and receives signals therefrom and/or controls them.

The handling station can in particular be part of a production line, in particular of an automated production line.

Provision is made in a possible embodiment that a control of the handling arrangement monitors a contact force and regulates it to a desired value.

Provision is made in a possible embodiment that a control of the handling arrangement controls the gripper and the joining and/or inspection unit such that a joining and/or inspection of the component takes place while it is held by the gripper.

In a possible embodiment, the joining and/or inspection unit or the handling station serves the installation and/or inspection of battery elements, in particular for the installation of battery modules and/or housing components at battery packs and/or of battery packs at a vehicle.

The present disclosure further comprises a method of operating a joining and/or inspection unit or a handling station such as has been described above.

The method can in particular comprise a step of joining and/or inspecting the component by one or more joining and/or inspection elements of the joining and/or inspection unit.

The method can in particular comprise a step of gripping the component by a gripper of the joining and/or inspection unit.

The method can in particular comprise the installation of battery elements, in particular for the installation of battery modules and/or housing components at battery packs and/or of battery packs at a vehicle.

In a possible embodiment, the contact force is monitored and is regulated to a desired value.

In a possible embodiment, a joining and/or inspecting of the component takes place while it is held in a desired position by the gripper.

In a possible embodiment, the method takes place such as is described above and in the following with regard to the deployment and/or operating possibilities and/or the use and/or operation of the handling arrangement and/or of the joining and/or inspection unit.

### BRIEF DESCRIPTION OF THE FIGURES

The present disclosure will now be described in more detail with reference to drawings and embodiments. There are shown:

FIG. 1: a first embodiment of a joining and/or inspection unit in accordance with the disclosure in a perspective representation;

FIG. 2: the embodiment shown in FIG. 1 in a side view;

FIG. 3: a second embodiment of a joining and/or inspection unit in accordance with the disclosure, with the joining and/or inspection elements not being shown for better clarity;

FIG. 4: a third embodiment of a joining and/or inspection unit in accordance with the disclosure in a perspective representation; and

FIG. 5: the embodiment shown in FIG. 4 in a side view.

### DETAILED DESCRIPTION

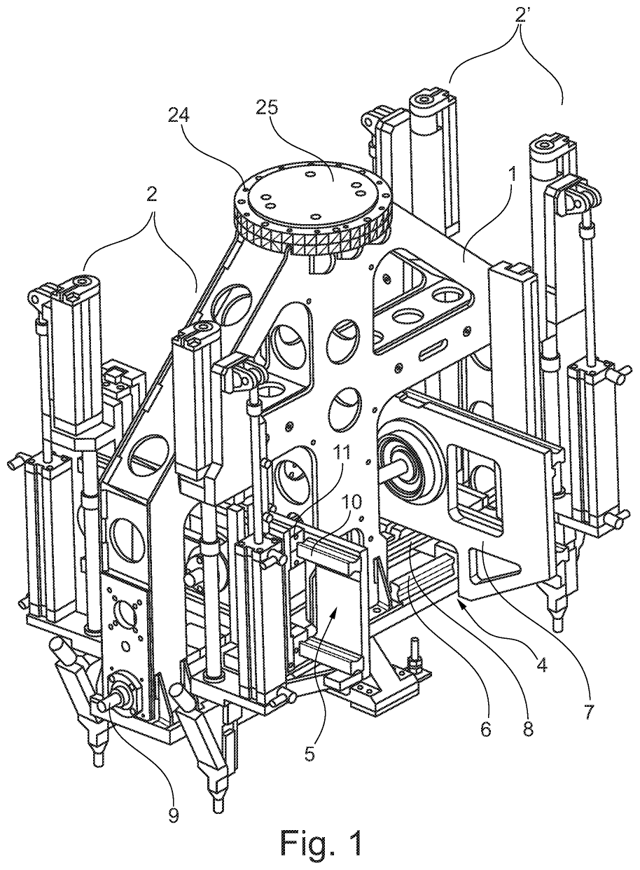

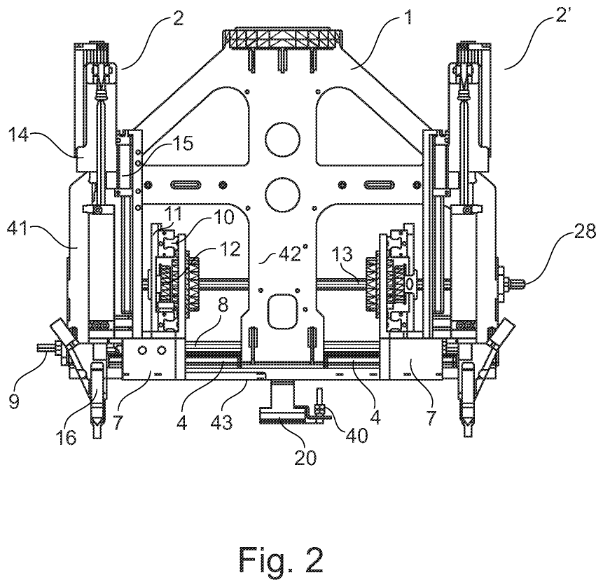

FIGS. 1 and 2 show a first embodiment of a joining and/or inspection unit in accordance with the disclosure having a base 1 at which a plurality of joining and/or inspection elements 2 and 2′ are arranged.

As can be seen in FIGS. 1 and 2, the joining and/or inspection elements in the embodiment are joining devices, in particular screwdrivers.

In the embodiment, they have a joining drive, in particular a screw driver 14, that drives a screwdriver shaft. A linear drive 15, in particular in the form of a pneumatic cylinder, is furthermore provided via which the screwdriver is travelable in the joining direction. An automatic fixing element supply 16 is furthermore provided, for the supply of screws here.

A screwdriver is, however, only an example for a joining and/or inspection element that can be used in accordance with the disclosure.

Other joining devices, for example riveting devices, could, for example, also be used instead of screwdrivers. The use of welding devices as joining and/or inspection elements is equally conceivable, in particular for spot welding. The joining and/or inspection elements can furthermore be actuation actuators for actuating a fastening element of the component. A fixing element already present on the component can, for example, be pressed in via such an actuation actuator.

An inspection element can furthermore also be provided instead of one or more of the joining devices.

The inspection element can, for example, be a contact element of an inspection device for measuring electrical properties of the component. The contact element is in particular configured to contact an electrical terminal of the component.

At least two contact elements can in particular be provided to contact electrical terminals of the component.

The inspection elements can, however, also be independent inspection devices.

The inspection elements can furthermore be inspection devices and/or components of inspection devices for inspecting other properties of the component, for example for inspecting optical or mechanical properties of the component.

The joining and/or inspection elements 2 and 2′ are arranged at the base 1 via an adjustment arrangement via which the spacing of the joining and/or inspection elements from one another is adjustable.

In the embodiment, a first adjustment axle 4 is provided here via which the spacing of the joining and/or inspection elements 2 from the joining and/or inspection elements 2′ can be varied. A second adjustment axle 5 is furthermore provided via which the spacing of the two joining and/or inspection elements 2 from one another and the spacing of the joining and/or inspection elements 2′ from one another can be varied.

The two adjustment axles 4 and 5 are arranged at the base 1 such that the spacing of the joining and/or inspection elements 2 and 2′ and thus the joining and/or inspection points at which they can join or inspect the component is adjustable in a plane.

in the embodiment, this plane and thus the directions of movement of the first and second adjustment axles 4 and 5 are perpendicular on the joining and/or inspection direction that is defined in the present case by the alignment of the screwdriver axis or the alignment of the linear axle 15 for moving the joining and/or inspection elements in the joining and/or inspection direction.

In the embodiment, the first and second adjustment axles are perpendicular to one another and thus serve the length and width adjustment of the joining and/or inspection elements.

In the embodiment, the base 1 is a weld construction at which the adjustment arrangement for the joining and/or inspection elements is arranged.

The base 1 comprises an installation section 25 by which is can be installed at an end member of a handling arrangement, for example at the end member of a robot arm.

In the embodiment, a force measuring unit 24 is furthermore provided that is provided between the base 1 and the installation section 25. In particular a contact force that is exerted on the component via the joining and/or inspection unit can be measured via this force measuring unit.

The joining and/or inspection unit can furthermore comprise abutment elements 20 by which it contacts an upper side of the component to press it into a predefined position. Alternatively or additionally, the abutment elements can also be used for a correct positioning of the joining and/or inspection unit at the component.

A contact sensor 40 is furthermore provided by which the contact between the joining and/or inspection unit and the component is monitored. In the embodiment, it is arranged at the abutment element 20.

The adjustment axles 4 and 5 are respectively designed as linear axles in the embodiment.

The first adjustment axle 4 comprises linear guides 6 at which the slides 7 are linearly displaceably arranged. Guides 10 of the second adjustment axles are in turn arranged at the slides 7 of the first linear axle. Slides 11 are linearly displaceably arranged at the guides 10 of the second adjustment axles.

In the embodiment, the joining and/or inspection elements 2, 2′ are each arranged at the slides 11 of the second adjustment axles.

In the embodiment, the first and second adjustment axles are each configured such that two slides displaceable at the guide are provided. In alternative embodiments, it would, however, likewise be conceivable to design the first and/or second adjustment axles with only one adjustable slide in each case.

In the embodiment, the first and second adjustment axles each allow a synchronous adjustment of the joining and/or inspection units arranged at it in the first or second adjustment directions. However, alternative configurations are also conceivable here in which no synchronous adjustment takes place.

In the embodiment, the adjustment of the slides 7 at the first adjustment axle takes place via a counter rotating trapezoidal spindle 8 that is supported at the base and engages at the sides 7. The spacing of the two slides 7 from one another can therefore be adjusted by rotating the trapezoidal spindle.

The trapezoidal spindle 8 has a drive shaft 9 at which, for example, a mechanically actuable adjustment element such as a handle, or a rotary wheel, or a drive, having a motor, for example, can engage.

The base 1 in the embodiment forms a frame that carries an installation plate at its lower side at which the linear guides 6 of the first adjustment axle are arranged. In the embodiment, the frame 41 comprises a center strut 42 that additionally supports the installation plate 43 at a center position. The respective linear guides 6 for the two slides 7 extend between the outer struts and the center strut 42 of the frame 41.

In the embodiment, the guides 6 are arranged on the side of the installation plate 43 remote from the component. The slides 7 furthermore extend on the side of the installation plate remote from the component in cutouts of the frame 41.

The slides 7 each carry installation plates that extend in the transverse direction and at which linear guides 10 of the second adjustment axle 5 are arranged. The slides 11 are linearly displaceably guided at the linear guides 10.

The two slides 7 are arranged symmetrically here in the embodiment.

The second adjustment axles in the embodiment comprise respective guide rails 10 for two slides 11 at which a respective joining and/or inspection element is arranged. In alternative configurations, however, only one respective slide 11 could be arranged at the two adjustment axles. For example, a diagonal arrangement of the slides 11 at the respective linear guides 10 of the two slides 7 would be conceivable.

In the embodiment, the guide rails 10 of the second adjustment axle each extend from the main plane of the fork-like frame 41 of the base 1. The slides 11 are arranged laterally next to the frame 41 such that the size of the joining and/or inspection elements is not restricted by the cutouts in the frame, but can be arranged next to them.

The slide 7, that carries the linear guides, and in particular the installation plate at which the linear guides 10 are arranged extends, however, through a cutout in the frame 41.

The linear guides 6 and 10 in the embodiment each have two guide elements that extend in parallel with one another to ensure a secure guidance. In the embodiment, the guide elements of the linear guide 6 extend next to one another in a horizontal plane; the guide elements of the linear guides 10 extend above one another in a vertical plane.

In the embodiment, the slides 11 are each adjustable symmetrically with one another.

The slides 11 of the second adjustment axles are furthermore adjustable at both slides 7 of the first adjustment axle via a common drive element, a torque shaft 13 in the embodiment.

The torque shaft 13 for this purpose drives respective drives 12 via which the adjustment of the slides 11 of the second adjustment axle takes place.

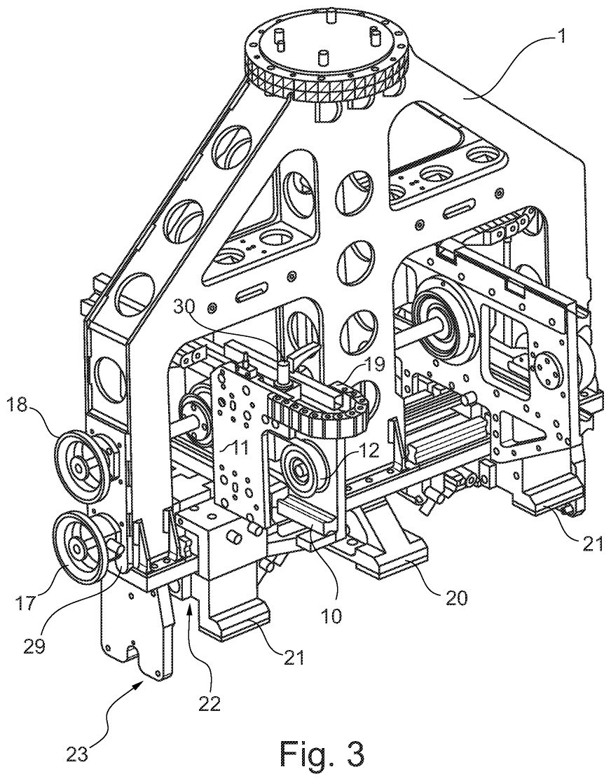

The drives 12 in the embodiment are belt drives. As can be more clearly recognized in FIG. 3 that shows an embodiment with the same basic design, with the joining and/or inspection elements not being shown in FIG. 3 for better clarity, pulleys over which a belt 12 runs are supported at the installation plates at which the second adjustment axles 5 rare arranged. The belt is driven via the torque shaft 13. The respective sides 11 are coupled to the belts so that they are adjusted on a movement of the belt along the linear guide 10.

The embodiment of the belt drives and their coupling to the slides 11 is configured such that the slides 11 are moved symmetrically to one another in the second direction or the width direction.

The drive of the torque shaft 13 takes place via the drive shaft 28 led out of the frame 41 in the embodiment. An actuation element for the mechanical actuation or a drive can in turn engage at said drive shaft 28.

The above-described constructive embodiments of the first and second adjustment axles are only exemplary designs that are used as part of the embodiment to enable an adjustment that is as reliable as possible. The use of alternative linear axles and alternative drives to drive such linear axles is, however, likewise conceivable.

The first and/or second adjustment axles can each have a fixing unit via which they can be fixed in a position settable by the respective adjustment axle. It can here, for example, be a clamping and/or latching unit.

In the embodiment, a clamping unit 29 is provided for the first adjustment axle 4. It acts on the trapezoidal spindle 8 in the embodiment. A clamping unit 30 is provided for the second adjustment axle. In the embodiment, it fixes the slides 11 to the linear guide 10.

FIG. 3 here shows an embodiment in which the first and second adjustment axles are each manually adjustable via handles 17 and 18. The fixing unit 29 or 30 is accordingly configured via hand levers.

In an alternative embodiment, the first and/or second adjustment axles are driven by motor, however. In this case, the fixing units may also be driven by motor.

The motor drive can take place such that an adjustment of the joining and/or inspection units can take place in a neutral clock cycle between the installation and/or inspection of two components. The joining and/or inspection unit can hereby be adapted to respective different components.

In the embodiment shown in FIGS. 1 and 2, a total of four joining and/or inspection elements are provided that are each arranged at the base 1 with longitudinal and width adjustment capability.

In alternative embodiments, however, only two joining and/or inspection elements could also be provided. Only one joining and/or inspection element could here in particular be displaceably arranged via a respective adjustment axle at each of the two slides 7 of the first adjustment axle.

In such an embodiment as is shown in FIG. 3, the joining and/or inspection elements 2, 2′ or the slides 11 for the joining and/or inspection elements may be arranged on oppositely disposed sides of the main plane of the frame 41 of the base 1 and/or are disposed diagonally opposite so that the spacing of the joining and/or inspection elements can be varied in the first direction via the first adjustment axle and the spacing of the joining and/or inspection elements can be varied in the second direction via the second adjustment axle.

The constructive design does not otherwise have to be changed in such an embodiment with respect to the design described with regard to FIGS. 1 and 2. Only a respective one of the two slides 11 is rather dispensed with. The base, the first adjustment axle, and/or the second adjustment axle can otherwise be designed such as has already been described above. We therefore refer with respect to the design of the embodiment in FIG. 3 to the description of the embodiment in FIGS. 1 and 2 to its full extent.

The joining and/or inspection unit can either be used to join, for example to screw or to rivet, a component to an installation position.

The joining and/or inspection unit can, however, also alternatively be used to install installation elements that serve the further installation of a component. These installation elements can in particular provide joining points for the component via which the component is installed at a base construction. In this case, the joining and/or inspection unit does not serve the joining of the component itself, but rather a pre-installation step by which the installation elements are joined.

The joining and/or inspection unit can furthermore be used to inspect a component. Inspection elements of the joining and/or inspection unit are for this purpose can be arranged with inspection points at the component and are in particular brought into contact with them.

In the embodiment shown in FIGS. 1 and 2, the joining and/or inspection unit does not comprise any gripper. It therefore serves either the pre-installation, as shown above, or the installation and/or inspection of a component otherwise gripped or already positioned.

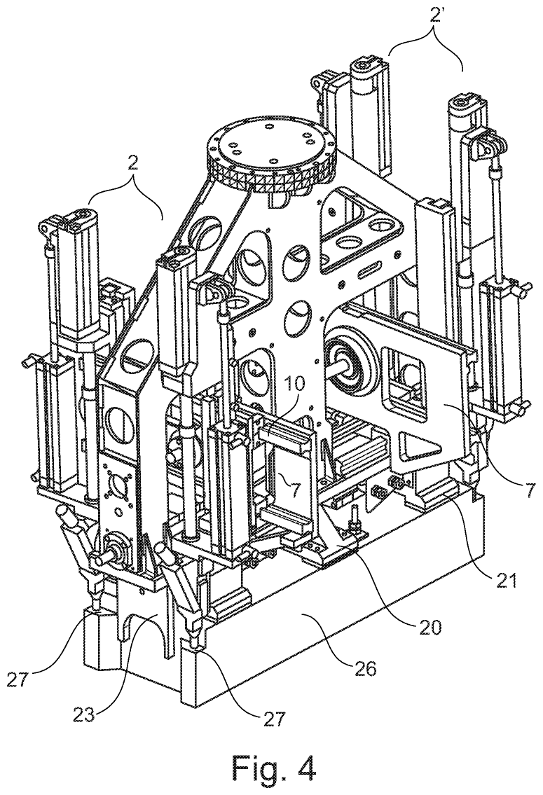

In alternative embodiments of the present disclosure such as will now be described with reference to the embodiments in FIGS. 3 and 4, the joining and/or inspection unit, however, furthermore comprises a gripper in addition to one or more joining and/or inspection elements 2, 2′.

The gripper in particular serves to grip a component and to place it at the installation location. The gripper can here hold the component while it is joined and/or inspected by the joining and/or inspection unit.

In a first variant, not shown, the gripper itself is not adjustable and only the joining and/or inspection units are adjustable relative to the gripper. In this case, components could be handled that do not differ with regard to their gripping points, but do with regard to their joining and/or inspection points.

In the embodiment, however, the gripper itself is adjustable so that components can be handled that differ both with regard to their gripping points and with regard to their joining and/or inspection points.

The gripper has two gripping actuators 22 for this purpose via which a respective gripping element 23 can be actuated. The position of at least one of the gripping actuators 22 at the base is adjustable via an adjustment axle so that the spacing between the gripping actuators 22, and thus the gripping elements 23, is settable.

In the embodiment, the first adjustment axle 4 here serves both the adjustment of the joining and/or inspection elements and the adjustment of the gripping actuators 22. The first adjustment axle in particular represents a common length adjustment for the gripping actuators and the joining and/or inspection elements. The spacing of the gripping actuators 22 is here adjustable together with the joining and/or inspection elements 2, 2′ in the first direction.

In the embodiment, the gripping actuators 22 are mechanical gripping actuators via which the gripping elements 23 can be moved toward one another or away from one another for gripping a component. The gripping elements 23 are gripping fingers or gripping jaws here.

In the embodiment, the direction of movement of the gripping actuators 22 is aligned in parallel with the first direction of the first adjustment axle.

In the embodiments shown in FIGS. 3 and 4, the second adjustment axle only serves the adjustment of the joining and/or inspection elements 2 or 2′.

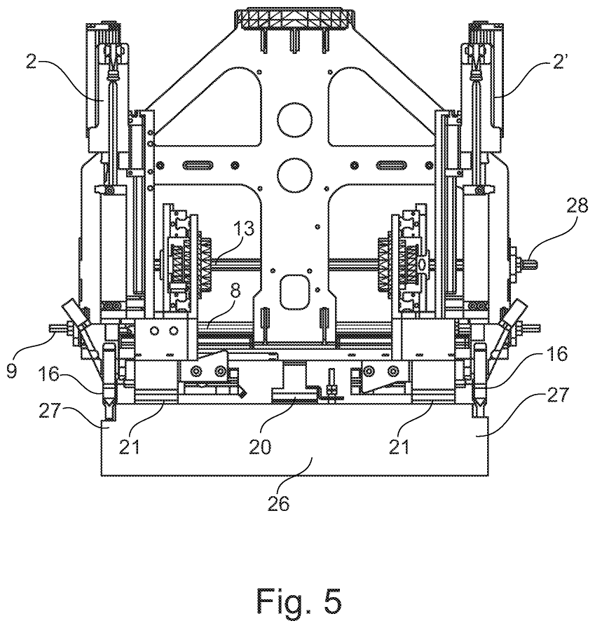

FIGS. 4 and 5 show the gripping of a component 26 by the gripper and the joining via the joining and/or inspection elements 2 and 2′.

The component 26 in the embodiment is gripped by the gripping elements 23 of the respective gripping actuators 22 on oppositely disposed sides. Joining is furthermore done at joining and/or inspection points 27 via the joining and/or inspection elements 2 and 2′ and/or joining is done, in particular installed at an installation base.

Abutment elements 20 and 21 are furthermore also provided here that lie on the upper side of the component 26 and can press it into a predefined position and/or by a defined force.

The joining and/or inspection unit can be used for gripping and joining and/or inspecting different components 26 by the first and second adjustment axles. Components can in particular be installed here that differ both with regard to their length and with regard to their width and thus the corresponding spacing of the gripping and/or joining and/or inspection points.

The constructive design of the embodiment shown in FIGS. 3-5 otherwise exactly corresponds to the constructive design that has already been described in more detail above with regard to FIGS. 1-3. We therefore refer in this respect to the above statements.

In addition to the embodiment in accordance with FIGS. 1-3, only the gripping actuators 22 are arranged at the slides 7 of the first adjustment axle.

Further abutment elements 21 are furthermore additionally provided that are likewise arranged at the slides 7 of the first adjustment axle and are therefore likewise adjustable via the first adjustment axle.

In the embodiment in FIG. 3, as already shown above, two diagonally arranged joining and/or inspection elements are provided. It would also be conceivable in alternative embodiments only to adjustably arrange a joining and/or inspection element at one of the slides 7.

In the embodiment shown in FIGS. 4 and 5, in contrast to the embodiment of FIGS. 1 and 2, a total of 4 joining and/or inspection elements are provided. The embodiment in FIGS. 4 and 5 here corresponds with regard to the joining and/or inspection elements and to the embodiment of the first and second adjustment axles to that of FIGS. 1 and 2 and only supplements it by the gripping actuators 22.

In a possible embodiment of the present disclosure, the first embodiment shown in FIGS. 1 and 2 and the embodiment shown in FIGS. 4 and 5 are used in sequential steps.

The first embodiment of a joining and/or inspection unit shown in FIGS. 1 and 2 can in particular be used for inspecting the component and/or for pre-installation, in particular for the pre-installation of fastening elements, and the embodiment shown in FIGS. 4 and 5 can then be used for the end installation of the corresponding component 26, in particular at the fastening elements.

Furthermore, in a configuration of the embodiment shown in FIGS. 4 and 5 with one or more inspection elements, a gripping of a component and an inspection of the component can take place.

A respective one or two joining elements and one or two inspection elements can equally be provided in the embodiment shown in FIGS. 4 and 5. Before the gripping, the component is inspected, e.g. the voltage at the two poles of a battery module provided as a component is determined and the battery module is subsequently gripped and then joined.

Since the joining points and the poles of the module representing the inspection points, are disposed at different points, the spacing of the joining elements and/or inspection elements is switched over between inspection and joining.

The joining and/or inspection units in accordance with the disclosure can in particular be used as part of automated handling stations, in particular of automated inspection and/or installation stations.

The joining and/or inspection unit can in particular be arranged at a handling arrangement, in particular a robot arm, and is moved by it.

The control of the handling arrangement and of the joining and/or inspection unit is programmed in a possible application such that a component is gripped, is placed at the installation position, and is installed there via the joining elements while it is still held by the gripper of the joining and/or inspection unit.

In a possible application, the control is programmed such that a component is inspected. This can be done before the gripping, while the component is gripped, or after it has been arranged at a destination location.

The two applications can be used in combination.

In a possible application, the control is programmed such that installation elements are installed by the joining and/or inspection unit.

If a first joining and/or inspection unit serves the pre-installation and/or inspection, a second joining and/or inspection unit the final installation, they may be arranged at two separate handling arrangements, in particular robot arms.

The robot arms can in particular be industrial robots, in particular industrial robots having at least six rotary joints, in particular 6-arm robots.

If the joining and/or inspection unit has a force measuring unit 24 as in the embodiments, the pressing force at which the component is pressed into the installation position can hereby be regulated by the control. The force that is applied to the component via the abutment elements 20 and 21 can thus in particular be regulated.

The robot control therefore in particular carries out a force and position regulation to install the component.

The present disclosure can in particular be used as part of the installation of automobile parts and/or battery modules.

The joining and/or inspection unit in particular serves the inspection and/or installation of battery modules in a battery pack, i.e. in an assembly having a plurality of battery modules, in particular in a battery pack of an electrically or hybrid-electrically operated vehicle.

In a possible embodiment, the battery module is fastened to a housing of the battery pack, for example screwed thereto, by the joining.

In a possible embodiment, an electrical property of the battery module is inspected, for example the voltage of the battery module, by the inspection.

In a possible application, defective battery modules are hereby recognized and sorted out.

The determination of the voltage can take place via two to four inspection elements that are brought into contact with a terminal of the battery module.

The joining and/or inspection unit can furthermore respectively comprise two joining elements and two inspection elements. A gripper can additionally be provided in a possible embodiment. The joining and/or inspection unit can in particular be designed such as is shown in FIGS. 1 and 2 or 4 and 5, with two joining elements and two inspection elements respectively being provided.

The control can be designed such that the voltage at the two poles of the battery module is determined in a first step, in particular before the gripping; the module is subsequently gripped and then joined. Since the joining points and the poles of the module are generally disposed at different positions, the spacing of the joining and/or inspection elements therebetween is switched over.

In a possible application case, the battery modules are pressed via the grippers of the joining and/or inspection unit into a viscous thermoconductive paste and is installed by the joining unit in this position. The force by which the battery module is pressed into the thermoconductive paste is monitored and regulated via the force measuring unit that is arranged between the handling arrangement and the joining and/or inspection unit. The position of the joining and/or inspection unit and thus of the battery module is additionally monitored and ensured by the handling arrangement. There is therefore a force deflection position regulation.

The battery module is subsequently fixed, for example screwed or riveted, at its desired position by the joining elements. The gripper of the joining and/or inspection unit has not yet gripped the battery module at this time and so ensures the desired position. Once the joining process has been completed, the gripper opens and the handling arrangement removes the gripper from the joined module.

Instead of robot arms, other handling arrangements are also conceivable to move the joining and/or inspection unit, for example linear and/or area portals.

It is possible by the adjustment arrangement of the joining and/or inspection unit to install different battery modules with the same joining and/or inspection unit. The battery modules can in particular differ both with regard to the spacing of the gripping points and with regard to the joining points and/or inspection points, in particular of the poles.

If the adjustment is made manually, the joining and/or inspection unit can be configured for the different battery modules in that the adjustment axles are manually actuated.

The adjustment of the adjustment axles may take place via drives, however, and is controllable via the control of the handling station. The adjustment may take place in a neutral clock cycle, i.e. between the gripping of two sequential battery modules.

Different application cases are also present in addition to the described application case of an installation of battery modules to form a battery pack, i.e. a battery unit having a plurality of battery modules.

For example, the joining and/or inspection unit can be used in the same way as described above for the installation of battery modules, for the installation of battery packs, i.e. units having a plurality of battery modules, at a vehicle chassis, in particular at a vehicle underside.

The joining and/or inspection unit can furthermore be used for installing housing elements of a battery pack, in particular of a cover of a battery pack.

The joining and/or inspection unit can also be used in different applications for inspecting and/or installing any other components.

The present disclosure here allows an exact, process-safe inspection and/or installation of components, in particular of battery modules, at a small clock cycle.

Individual process steps that are automatically carried out by the control in particular include the exact positioning, optionally with a force monitoring, the fixing of the component, and the release of the grip once the component has been fixed.

As part of the use of the present disclosure, a production of a batch size 1 is possible, i.e. an automatic equipping of the joining and/or inspection unit in cycle, e.g. during the component change, with the joining and/or inspection unit being respectively adapted to the next component to be installed by the adjustment arrangement.

A control of the handling station in particular recognizes the respective component to be installed next and controls drives of the adjustment arrangement such that the joining and/or inspection elements and/or gripping actuators are adapted to the joining points and/or gripping points and/or inspection points of the component.

In the embodiment, the joining and/or inspection elements are only adjustable together with the gripping actuators via the first adjustment axle. This requires that the position of the gripping points at the joining points and/or inspection points for the different components is respectively identical in the first direction, at least when the inspection and/or the joining takes place when the component is gripped.

Alternatively, the joining and/or inspection elements could, however, also be movable relative to the respective gripping actuators in the first direction via a further adjustment axle. Such a further adjustment axle may be arranged at the slides 7 of the first adjustment axle so that the rough positioning takes place in the first direction via the first adjustment axle in common for the joining and/or inspection elements and the gripping actuators and the fine positioning takes place via the further adjustment axle. Either the joining and/or inspection elements or the gripping actuators are then arranged at this further adjustment axle.

FIGS. 1-5 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A joining and/or inspection unit for joining and/or inspecting a component having a base and a plurality of joining and/or inspection elements, wherein the joining and/or inspection elements are arranged at the base such that they each establish a connection and/or an inspection at a joining and/or inspection point of the component,
wherein
the joining and/or inspection elements are arranged at the base via an adjustment arrangement that allows an adjustment of a spacing of the joining and/or inspection elements from one another.

2. The joining and/or inspection unit in accordance with claim 1, wherein the spacing of the joining and/or inspection elements and/or of the joining and/or inspection points is adjustable in a plane.

3. The joining and/or inspection unit in accordance with claim 1, having at least one gripper for gripping the component, wherein the at least one gripper allows a holding of the component while the component is joined and/or is inspected by the joining and/or inspection elements.

4. The joining and/or inspection unit in accordance with claim 3, wherein the at least one gripper comprises at least two gripping actuators via which gripping elements for gripping the component can be actuated, with the at least two gripping actuators being arranged above the adjustment arrangement at the base such that spacing of the at least two gripping actuators from one another is adjustable.

5. A joining and/or inspection unit for joining and/or inspecting a component having a base, a gripper, and one or more joining and/or inspection elements, wherein the gripper comprises at least two gripping actuators via which gripping elements for gripping the component can be actuated, and with the one or more joining and/or inspection elements being arranged at the base such that they each establish a connection and/or carry out an inspection at a joining and/or inspection point of the component,
wherein
the at least two gripping actuators and the one or more joining and/or inspection elements are arranged at the base via an adjustment arrangement via which spacing of the at least two gripping actuators and/or of the joining and/or inspection elements is adjustable with respect to one another.

6. The joining and/or inspection unit in accordance with claim 5, wherein the gripper is a mechanical gripper and the at least two gripping actuators move the gripping elements along a first direction to grip the component, with spacing between the at least two gripping actuators being adjustable in the first direction by the adjustment arrangement to adapt the gripper to components of different sizes.

7. The joining and/or inspection unit in accordance with claim 5, wherein the at least two gripping actuators and the one or more joining and/or inspection elements are adjustable together via at least a first adjustment axle, and/or wherein only the one or more joining and/or inspection elements are adjustable via at least a second adjustment axle.

8. The joining and/or inspection unit in accordance with claim 1, wherein first and/or second adjustment axles is/are designed such that it/they carries/carry put a symmetrical adjustment of at least two joining and/or inspection elements and/or gripping actuators relative to the base.

9. The joining and/or inspection unit in accordance with claim 8, wherein the first adjustment axle comprises two first slides that are travelable along a linear guide relative to the base via a first drive element;
wherein the second adjustment axle is arranged at each of the two first slides, with the second adjustment axle comprising one or two second slides that is/are each travelable along a linear guide arranged at the first slide via a second drive element; and
wherein the second drive elements are drivable together via a third drive element.

10. The joining and/or inspection unit in accordance with claim 1, having one or more fixing units for fixing first and/or second adjustment axles, with there being one or more clamping and/or latching units.

11. The joining and/or inspection unit in accordance with claim 1, having one or more abutment elements that contact an upper side of the component to press it into position; and/or having a force measuring unit for measuring a contact force.

12. The joining and/or inspection unit in accordance with claim 1, wherein one or more of the joining and/or inspection elements are joining devices and/or welding devices and/or actuating actuators for actuating a fastening element of the component, and/or wherein one or more of the joining and/or inspection elements is/are elements of a test device for inspecting electrical properties of the component.

13. A handling station having a handling arrangement and a joining and/or inspection unit in accordance with claim 1, wherein the joining and/or inspection unit is arranged at the handling arrangement and is moved thereby.

14. The joining and/or inspection unit in accordance with claim 1 for installing and/or inspecting battery elements.

15. A method of operating a joining and/or inspection unit or a handling station in accordance with claim 1,
wherein a contact force is monitored and is regulated to a desired value, and/or wherein a joining and/or inspection of the component takes place while it is held by the at least one gripper.

16. The joining and/or inspection unit in accordance with claim 1, wherein the adjustment arrangement comprises a first and second adjustment axle via which the spacing of the joining and/or inspection elements from one another is adjustable in a first and second direction.

17. The joining and/or inspection unit in accordance with claim 5, wherein the at least two gripping actuators are adjustable in at least a first direction via at least a first adjustment axle and/or with the one or more joining and/or inspection elements being adjustable in at least a second direction with respect to the gripping actuators or to one another via at least a second adjustment axle.

18. The joining and/or inspection unit in accordance with claim 7, wherein a first gripping actuator is arranged together with a first joining and/or inspection element or a group of first joining and/or inspection elements at an adjustment element of the first adjustment axle, with a second adjustment axle being arranged at the adjustable element via which the first joining and/or inspection elements are adjustable with respect to one another and/or to the at least two gripping actuators.

19. The handling station in accordance with claim 13, wherein control of the handling arrangement is monitoring a contact force and regulating it to a desired value and/or controlling the gripper and the joining and/or inspection unit such that a joining and/or inspection of the component takes place while it is held by the gripper.

20. The handling station in accordance with claim 13 for installing and/or inspecting battery elements.
